(19) United States
(12) Patent Application Publication
(10) Pub. No.: US 2010/0006423 A1
(43) Pub. Date: Jan. 14, 2010

(54) MAGNETIC FIELD GENERATION CONTROL UNIT AND MAGNETRON SPUTTERING APPARATUS AND METHOD USING THE SAME

(75) Inventors: Yun-Mo CHUNG, Yongin-City (KR); Ki-Yong Lee, Yongin-City (KR); Min-Jae Jeong, Yongin-City (KR); Heung-Yeol Na, Yongin-City (KR); Jong-Won Hong, Yong-City (KR); Eu-Gene Kang, Yongin-City (KR)

Correspondence Address: STEIN MCEWEN, LLP, 1400 EYE STREET, NW, SUITE 300, WASHINGTON, DC, 20005, US

(73) Assignee: Samsung Mobile Display Co. Ltd., Yongin-City (KR)

(21) Appl. No.: 12/481,239

(22) Filed: Jun. 9, 2009

(30) Foreign Application Priority Data
Jul. 9, 2008 (KR) 2008-66723

(51) Int. Cl. C23C 14/35

(52) U.S. Cl. 204/192.12; 204/298.16

(57) ABSTRACT

A magnetic field generation control unit and a magnetron sputtering apparatus and method using the magnetic field generation control circuit. The magnetic field generation control unit includes a magnetic field generator for providing a specific magnetic field to a target consisting of a metal material to be deposited on a substrate, and a magnetic field generator control module electrically connected with the magnetic field generator, receiving an electrical signal from outside, and selectively supplying a current capable of generating the magnetic field to the magnetic field generator. The target is prevented from being magnetized when a sputtering process is not performed, and the magnetic field is generated from the target when the process is performed. Consequently, it is possible to perform uniform deposition on the substrate.

### CROSS-REFERENCE TO RELATED APPLICATION

This application claims the benefit of Korean Application No. 10-2008-0066723, filed in the Korean Intellectual Property Office on Jul. 9, 2008, the disclosure of which is incorporated herein by reference.

### BACKGROUND OF THE INVENTION

1. Field of the Invention

Aspects of the present invention relate to a magnetron sputtering apparatus, and more particularly, to a magnetic field generation control circuit capable of preventing a target from being magnetized and performing uniform deposition on a substrate, a magnetron sputtering apparatus having the magnetic field generation control circuit, and a magnetron sputtering method using the magnetic field generation control circuit.

2. Description of the Related Art

In the fabrication process of a semiconductor or liquid crystal display (LCD), a thin film process is typically performed to pattern a specific thin film or form a circuit pattern on an object to be processed, which is a parent material such as a wafer or a glass substrate. In the fabrication process of an LCD, a metal layer for forming a gate line and a data line and a transparent conductive film for forming a pixel electrode and a common electrode are deposited on a glass substrate using a sputtering method, and patterned to form a specific circuit pattern.

According to the sputtering method, a process gas, such as argon or helium, is injected into a process chamber in a vacuum atmosphere to create a plasma atmosphere. The plasma ions are collided with a target, and atoms emitted from the target are deposited on a substrate. Lately, the sputtering method has been advanced. A magnetron sputtering method of causing plasma ions to impinge around the target is used.

FIG. 1 shows a conventional magnetron sputtering apparatus. The conventional magnetron sputtering apparatus includes a process chamber 100 having a gas inlet pipe 110 and a gas outlet pipe 120, a substrate support 130 installed in the process chamber 100 and on which a substrate 140 is placed, a magnet 50 disposed above the substrate support 130 in the process chamber 100, a fixing plate 60 fixing the magnet 50 in the upper part of the process chamber 100, and a target 200 disposed between the magnet 50 and the substrate support 130.

According to the above constitution, the magnet 50 generates a stronger magnetic field than a specific force and magnetizes the target 200 to generate a magnetic field required for a process. In this situation, when a plasma atmosphere is created in the process chamber 100 under vacuum, plasma ions may impinge around the magnetized target 200.

Since a specific amount or more of plasma ions are gathered around the target 200 and collide against the target 200, a comparatively large amount of atoms of the target 200 can be emitted from the target 200 and deposited on the substrate 140 at a comparatively high rate. Such a magnetron sputtering apparatus facilitates control of the amount of deposited metal (such as nickel) and can be easily applied to a large substrate, and thus has been widely used.

Unlike metal induced crystallization (MIC) or metal induced lateral crystallization (MILC), according to super grain silicon (SGS) crystallization, metal must be deposited on a substrate at a low concentration of, for example, 1011 to 1016 or less atom/cm². Thus, it is very important to control the uniformity and rate of deposition on the substrate 140. However, in the sputtering apparatus as shown in FIG. 1, the magnet 50 generates a uniform magnetic field even after the sputtering process is performed, and thus generates a uniform magnetic field from the target 200. Since the target 200 continues to generate the uniform magnetic field even if the process is not performed, the target is magnetized and distorted.

According to the conventional art, it is impossible to guarantee the deposition uniformity of metal deposited on the substrate 140 during the process due to the magnetized target 200. In addition, when metal is deposited on the large substrate 140, a separated magnetic field of the target 200 cannot be generated for a partial area. Thus, it is impossible to modify the deposition uniformity of a thin film deposited on the substrate 140.

### SUMMARY OF THE INVENTION

Aspects of the present invention provide a magnetic field generation control unit that selectively controls magnetic field generation toward a target according to whether a sputtering process is performed on a substrate to prevent the target from being magnetized when the sputtering process is not performed and to generate a magnetic field toward the target and perform uniform deposition on the substrate when the sputtering process is performed, a magnetron sputtering apparatus having the magnetic field generation control unit, and a magnetron sputtering method using the magnetic field generation control unit.

Additional aspects of the present invention provide a magnetic field generation control unit that reciprocates a target below a magnetron, which is a magnetic field generator, during a sputtering process and thus can uniformly deposit target material on a substrate; a magnetron sputtering apparatus having the magnetic field generation control unit; and a magnetron sputtering method using the magnetic field generation control unit.

According to an aspect of the present invention, a magnetic field generation control unit is provided. The magnetic field generation control unit includes: a magnetic field generator to provide a specific magnetic field to a target having a metal material to be deposited on a substrate; and a magnetic field generator control module electrically connected with the magnetic field generator, to receive an electrical signal, and to selectively supply a current capable of generating the magnetic field to the magnetic field generator.

According to another aspect of the present invention, the magnetic field generator further include: an inner ferrite formed in the shape of a bar having a specific length; a coil wound around the inner ferrite; and an outer ferrite surrounding the coil and having an external surface coated with nickel.

According to another aspect of the present invention, the magnetic field generator further includes: an inner ferrite having a bar shape having a specific length; an inner coil wound around the inner ferrite; an outer coil wound around the inner coil; and an outer ferrite surrounding the outer coil and having an external surface coated with nickel.

According to another aspect of the present invention, the magnetic field generation control unit further comprises only one magnetic field generator, and the one magnetic field generator is spaced apart from one surface of the target by a specific distance.

According to another aspect of the present invention, the magnetic field generation control unit further comprises a plurality of the magnetic field generators parallel to each other and spaced apart from one surface of the target by a specific distance.

According to another aspect of the present invention, the magnetic field generation control unit further includes a process controller electrically connected with the magnetic field generator control module to control a process of depositing the metal material on the substrate, and the process controller transfers the electrical signal to the magnetic field generator control module when the process of depositing the metal material on the substrate is performed.

According to another aspect of the present invention, a magnetron sputtering apparatus having a magnetic field generation control unit is provided. The apparatus includes: a process chamber having a substrate support on which a substrate is placed; a target installed above the substrate support in the process chamber, including a metal material to be deposited on the substrate, and arranged so as to be movable along a specific reciprocating movement path; a magnetic field generator installed above the target in the process chamber, to provide a specific magnetic field to the target; a process controller to control a process of depositing the metal material on the substrate; and a magnetic field generator control module electrically connected with the process controller and the magnetic field generator, to receive an electrical signal indicating whether the process is performed from the process controller, to selectively move the target, and to selectively supply a current capable of generating the magnetic field to the magnetic field generator.

According to another aspect of the present invention, the magnetron sputtering apparatus further includes a movement unit connected with the target, the movement unit including a fixing frame to fix both sides of the target, a guide frame to guide a sliding movement of the fixing frame, and a linear motor to slide the fixing frame.

According to another aspect of the present invention, the magnetic field generator control module includes a movement controller and a current supply controller, the movement controller is electrically connected with the linear motor, and the current supply controller is electrically connected with the magnetic field generator. When the process of depositing the metal material on the substrate is performed, the magnetic field generator control module receives the electrical signal indicating that the process is performed from the process controller, reciprocate the target using the movement controller, and supply the specific current to the magnetic field generator using the current supply controller.

According to another aspect of the present invention, a length direction of the magnetic field generator may cross the reciprocating movement path at right angles.

According to another aspect of the present invention, a length of the magnetic field generators may be in the same direction as the reciprocating movement path.

According to another aspect of the present invention, a magnetron sputtering method using a magnetic field generation control unit is provided. The method includes: determining, at a process controller, whether a process of depositing a metal material of a target on a substrate is performed; and determining, at a magnetic field generator control module, whether to supply a current for generating a magnetic field to a magnetic field generator for generating a magnetic field from the target according to whether the process is performed.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 illustrates a conventional magnetron sputtering apparatus;

FIG. 2 illustrates a magnetron sputtering apparatus according to an embodiment of the present invention;

FIG. 3 is an enlarged view of a part of FIG. 2 indicated by a reference numeral A;

FIG. 4 illustrates an example of the magnetic field generator of FIG. 2;

FIG. 5 illustrates another example of the magnetic field generator of FIG. 2;

FIG. 6 illustrates a magnetron sputtering apparatus according to another embodiment of the present invention;

FIG. 7 illustrates an example of the magnetic field generator of FIG. 6;

FIG. 8 illustrates another example of the magnetic field generator of FIG. 6;

FIG. 9 is a flowchart showing operation of a magnetic field generation control unit according to an embodiment of the present invention; and

FIG. 10 is a flowchart showing operation of a magnetic field generation control unit according to another embodiment of the present invention.

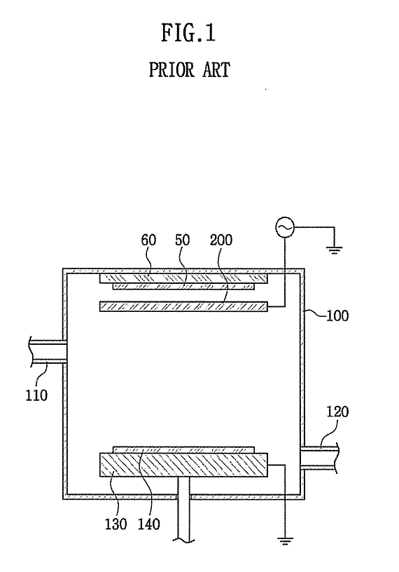

### DETAILED DESCRIPTION OF THE EMBODIMENTS

Reference will now be made in detail to the present embodiments of the present invention, examples of which are illustrated in the accompanying drawings, wherein like reference numerals refer to like elements throughout. The embodiments are described below in order to explain the present invention by referring to the figures.

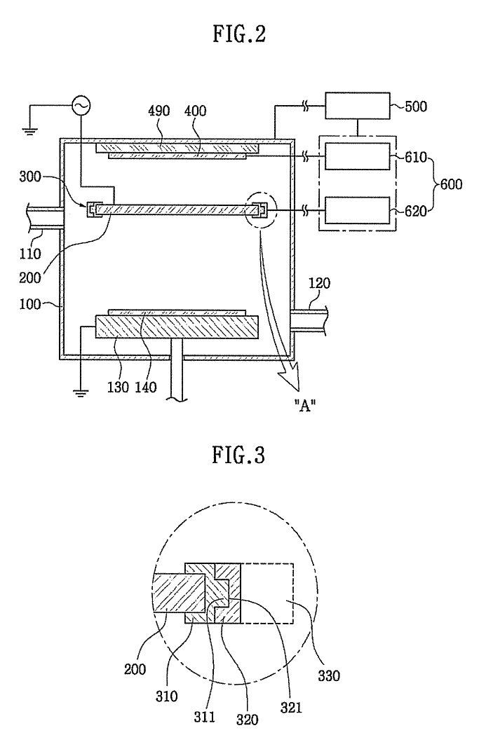

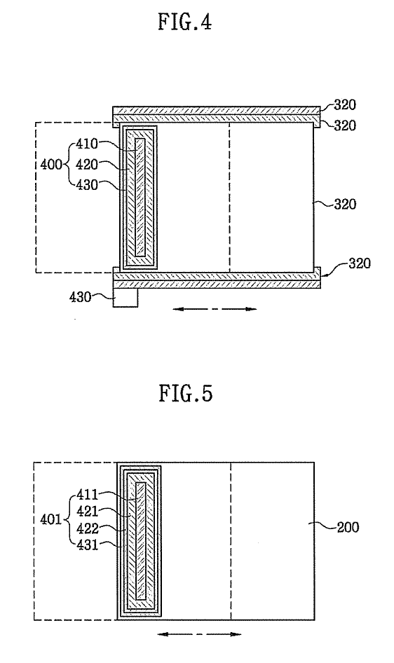

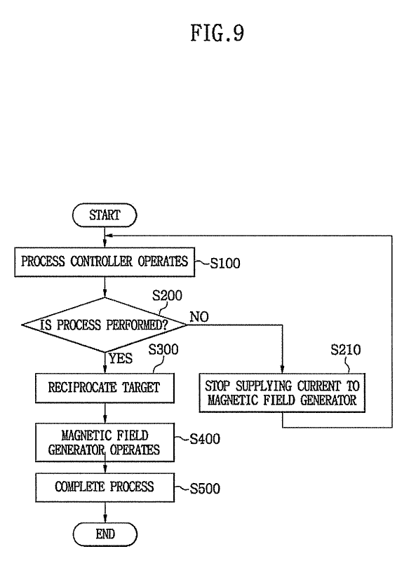

FIG. 2 shows a magnetron sputtering apparatus according to an embodiment of the present invention. FIG. 3 is an enlarged view of a part of FIG. 2 indicated by a reference numeral A. FIG. 4 shows an example of a magnetic field generator of FIG. 2. FIG. 5 shows another example of the magnetic field generator of FIG. 2. FIG. 9 is a flowchart showing operation of a magnetic field generation control unit according to an embodiment of the present invention.

As shown in FIG. 2, the magnetron sputtering apparatus having a magnetic field generation control unit includes a process chamber 100, a target 200, a magnetic field generator 400, a process controller 500 and a magnetic field generator control module 600. The process chamber 100 has a substrate support 130 on which a substrate 140 is placed. The target 200 is installed above the substrate support 130 in the process chamber 100, and includes a metal material to be deposited on the substrate 140. The target 200 is arranged so as to be movable along a specific reciprocating movement path. The magnetic field generator 400 is installed above the target 200 in the process chamber 100, and provides a specific magnetic field to the target 200. The process controller 500 controls a process of depositing the metal material onto the substrate 140. The magnetic field generator control module 600 is electrically connected with the process controller 500 and the magnetic field generator 400, and receives an electrical signal indicating whether the process is performed from the process controller 500 to selectively move the target 200 and to selectively supply a current capable of generating the magnetic field to the magnetic field generator 400.

The process chamber 100 has a gas inlet pipe 110 on one side, through which inert gas is injected, and a gas outlet pipe 120 on another side, through which gas is exhausted. The target 200 is connected with a movement unit 300.

The movement unit 300 includes a fixing frame 310 that fixes both sides of the target 200, a guide frame 320 that guides the sliding movement of the fixing frame 310, and a linear motor 330 that slides the fixing frame 310. A sliding protrusion 311 is formed on the fixing frame 310, and a sliding hole 321 in which the sliding protrusion 311 is inserted is formed in the guide frame 320 to guide the sliding movement of the fixing frame 310. As a result, the target 200 can be reciprocated along the reciprocating movement path in a specific reciprocating section by the linear motor 330.

The process controller 500 controls the process. For example, the process controller 500 may put the substrate 140 on the substrate support 130, create a vacuum required for the process in the process chamber 100 or inject the inert gas into the process chamber 100, thereby allowing the sputtering process to proceed. The magnetic field generator 400 is fixed on a fixing plate 490 installed in the upper part within the process chamber 100 to be disposed above the target 200.

As shown in FIGS. 4 and 5, the magnetron sputtering apparatus may include the magnetic field generator 400 or a magnetic field generator 401, each having a specific length. Here, the width direction of the magnetic field generator 400 crosses the reciprocating movement path of the target 200 at right angles.

The magnetic field generator 400 may be a single coil type as shown in FIG. 4. The magnetic field generator 400 shown in FIG. 4 includes an inner ferrite 410 that is formed in the shape of a bar having a specific length, a coil 420 wound around the inner ferrite 410, and an outer ferrite 430 surrounding the coil 420 and having an external surface coated with nickel.

The magnetic field generator 401 may be a dual coil type as shown in FIG. 5. The magnetic field generator 401 shown in FIG. 5 may include an inner ferrite 411 that is formed in the shape of a bar having a specific length, an inner coil 421 wound around the inner ferrite 411, an outer coil 422 wound around the inner coil 421, and an outer ferrite 431 surrounding the outer coil 422 and having an external surface coated with nickel.

The magnetic field generator control module 600 includes a movement controller 620 and a current supply controller 610 electrically connected with the process controller 500 as shown in FIG. 2. The movement controller 620 is electrically connected with the linear motor 330. The current supply controller 610 is electrically connected with the magnetic field generator 400 or 401.

When the process of depositing the metal material on the substrate 140 is performed, the magnetic field generator control module 600 may receive the electrical signal indicating that the process is performed from the process controller 500, reciprocate the target 200 using the movement controller 620, and supply a specific current to the magnetic field generator 400 or 401 using the current supply controller 610 such that a specific magnetic field can be generated.

Operation of the magnetron sputtering apparatus shown in FIG. 2 will be described with reference to FIGS. 2, 3, 4, 5 and 9. Referring to FIGS. 2 and 9, the process controller 500 prepares a sputtering process in operation 100. The process controller 500 operates a vacuum pump (not shown) capable of creating a vacuum in the process chamber 100, moves and prepares the substrate 140 on the substrate support 130 using a transfer device (not shown), or injects inert gas from a gas supplier (not shown) into the process chamber 100 through the gas inlet pipe 110.

The process controller 500 transfers an electrical signal indicating that the process is performed to the magnetic field generator control module 600 while preparing the process as described above. In operation 200, the magnetic field generator control module 600 determines whether the sputtering process is performed based on the electrical signal.

If the sputtering process is performed as described above, the movement controller 620 of the magnetic field generator control module 600 may control the movement unit 300 to operate. In operation 300, the linear motor 330 of the movement unit 300 operates such that the target 200 can reciprocate along the reciprocating movement path in a specific section at a specific rate as shown in FIGS. 4 and 5.

The current supply controller 610 of the magnetic field generator control module 600 supplies a specific current to the magnetic field generator 400 or 401. In operation 400, the magnetic field generator 400 or 401 supplied with the current generates a specific magnetic field.

The current supply controller 610 supplies the current to the magnetic field generator 400 or 401. A magnetic field can be generated from the lower surface of the target 200 to have a strength of 200 to 800 gauss by a magnetic field generated by the magnetic field generator 400 or 401. While the target 200 reciprocates along the reciprocating movement path below the magnetic field generator 400 or 401, the magnetic field generator 400 or 401 may magnetize the target 200 using the specific magnetic field.

The inert gas is injected into the process chamber 100 under vacuum, such that plasma can be generated in the process chamber 100. The plasma ions are gathered around the magnetized target 200 and collide against the target 200, and atoms emitted from the target 200 due to the collision may be deposited on the upper surface of the substrate 140 at a high rate.

If no electrical signal is received from the process controller 500, the magnetic field generator control module 600 determines that the sputtering process is not performed. The movement controller 620 of the magnetic field generator control module 600 then prevents the linear motor 330 from operating, thereby stopping movement of the target 200. In operation 210, the current supply controller 610 of the magnetic field generator control module 600 stops the current from being supplied to the magnetic field generator 400 or 401. As a result, the magnetic field generator 400 or 401 will not generate a magnetic field.

Consequently, the magnetic field generator control module 600 can prevent the target 200 from being magnetized by the magnetic field generator 400 or 401 while the sputtering process is not performed. In addition, when the dual coil type magnetic field generator 401 is used as shown in FIG. 5, the inner coil 421 and the outer coil 422 may have opposite polarities, such that the effect of an unbalanced magnetron deposition source can be obtained.

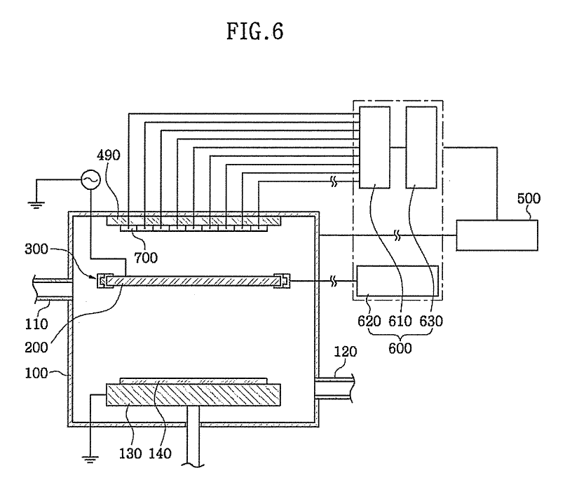

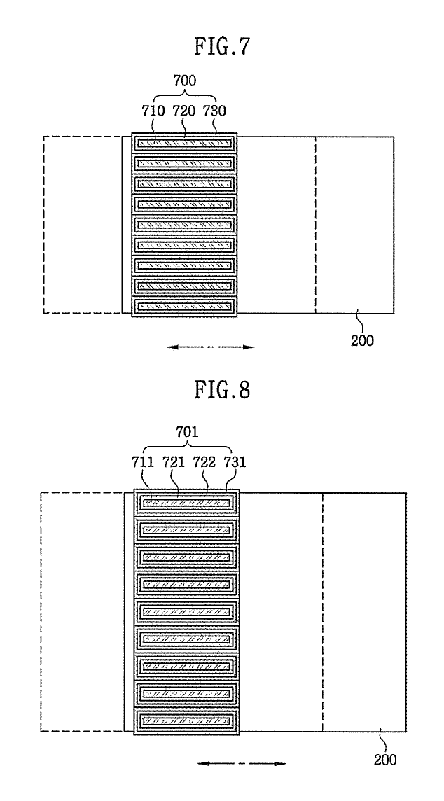

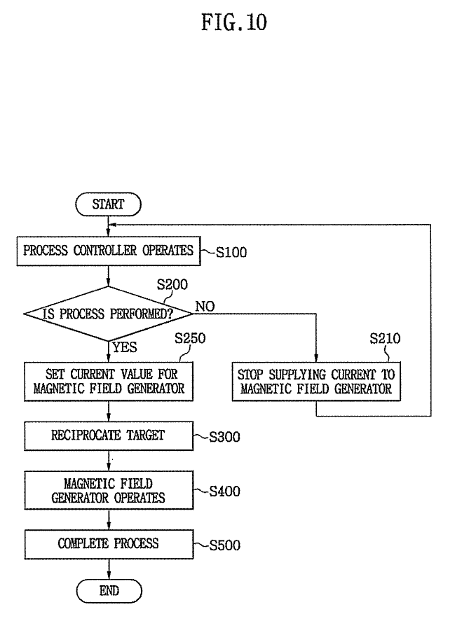

A magnetron sputtering apparatus according to another embodiment of the present invention will be described with reference to FIGS. 6, 7, 8 and 10. FIG. 6 shows a magnetron sputtering apparatus according to another embodiment of the present invention. FIG. 7 shows an example of the magnetic field generator of FIG. 6. FIG. 8 shows another example of the magnetic field generator of FIG. 6. FIG. 10 is a flowchart showing operation of a magnetic field generation control unit according to another embodiment of the present invention.

Referring to FIG. 6, the magnetron sputtering apparatus according to another embodiment of the present invention includes a process chamber 100, a substrate support 130, a target 200, a movement unit 300 that reciprocates the target 200 along a reciprocating movement path, and a process controller 500, which are similar to the corresponding units described above with respect to FIG. 2. The magnetron sputtering apparatus as shown in FIG. 6 includes a magnetic field generator 700 or 701 and a magnetic field generator control module 600, which are different from those of the magnetron sputtering apparatus shown in FIG. 4.

The magnetic field generator 700 or 701 is fixed on a fixing plate 490 installed in the upper part within the process chamber 100 to be disposed above the target 200. As shown in FIGS. 7 and 8, there are a plurality of the magnetic field generators 700 and 701 parallel to each other and spaced apart from one surface of the target 200 by a specific distance. The length of the magnetic field generators 700 and 701 may be in the same direction as the reciprocating movement path.

As shown in FIG. 7, the magnetic field generator 700 is a single coil type. The magnetic field generator 700 includes an inner ferrite 710 that is formed in the shape of a bar having a specific length, a coil 720 wound around the inner ferrite 710, and an outer ferrite 730 surrounding the coil 720 and having an external surface coated with nickel.

The magnetic field generator 701 may be a dual coil type as shown in FIG. 8. The magnetic field generator 701 may include an inner ferrite 711 that is formed in the shape of a bar having a specific length, an inner coil 721 wound around the inner ferrite 711, an outer coil 722 wound around the inner coil 721, and an outer ferrite 731 surrounding the outer coil 722 and having an external surface coated with nickel.

The magnetic field generator control module 600 includes a movement controller 620, a current supply controller 610 and a current value input unit 630 electrically connected with the process controller 500 as shown in FIG. 6. The movement controller 620 is electrically connected with a linear motor 330. The current supply controller 610 is electrically connected with the magnetic field generator 700. The current value input unit 630 is electrically connected with the current supply controller 610 and may separately input the values of currents to be supplied to the magnetic field generators 700 into the current supply controller 610.

When a process of depositing a metal material on a substrate 140 is performed, the magnetic field generator control module 600 may receive an electrical signal indicating that the process is performed from the process controller 500, reciprocate the target 200 using the movement controller 620, and supply a specific current to the magnetic field generator 700 using the current supply controller 610 such that a specific magnetic field is generated.

Operation of the magnetron sputtering apparatus shown in FIG. 6 will be described with reference to FIGS. 6, 7, 8 and 10. Referring to FIGS. 6 and 10, the process controller 500 prepares a sputtering process in operation 100. The process controller 500 transfers an electrical signal indicating that the process is performed to the magnetic field generator control module 600 while preparing the process as described above. In operation 200, the magnetic field generator control module 600 determines whether the sputtering process is to be performed based on the electrical signal.

If the sputtering process is to be performed, the current value input unit 630 of the magnetic field generator control module 600 inputs the values of currents to be separately supplied to the magnetic field generators 700 into the current supply controller 610 and sets the current values in operation 250.

The separate currents may be supplied from the current supply controller 610 to the respective magnetic field generators 700 disposed above the target 200. The current value input unit 630 selectively inputs the values of the currents to be supplied to the magnetic field generators 700 into the current supply controller 610, and the magnetic field generators 700 are aligned in parallel in the movement direction of the target 200. The current value input unit 630 may input the values of the currents into the current supply controller 610 such that currents can be supplied only to the magnetic field generators 700 corresponding to the width of the target 200.

Since only the magnetic field generators 700 corresponding to various widths of the target 200 are operated, targets having various widths can be easily magnetized. In addition, the magnetic field generators 700 can generate magnetic fields using different currents due to the current value input unit 630. As a result, the uniformity of a thin film deposited on the substrate 140 after the sputtering process may be easily modified in the following process.

In operation 300, the movement controller 620 of the magnetic field generator control module 600 controls the movement unit 300 to operate. The linear motor 330 of the movement unit 300 operates to reciprocate the target 200 along the reciprocating movement path in a specific section at a specific rate as shown in FIGS. 7 and 8.

The current supply controller 610 of the magnetic field generator control module 600 may supply the currents according to the current values input from the current value input unit 630 to the respective magnetic field generators 700 or 701. The magnetic field generators 700 or 701 supplied with the currents then generate a specific magnetic field. The current supply controller 610 supplies the currents to the magnetic field generators 700 or 701. A magnetic field can be generated from the lower surface of the target 200 to have a strength of 200 to 800 gauss by the magnetic field generated by the magnetic field generators 700 or 701.

While the target 200 reciprocates along the reciprocating movement path a below the magnetic field generators 700 or 701, the magnetic field generators 700 or 701 may magnetize the reciprocating target 200 using the specific magnetic field. In addition, inert gas is injected into the process chamber 100 under vacuum, such that plasma can be generated in the process chamber 100. Subsequently, the plasma ions are gathered around the magnetized target 200 and collide against the target 200, and atoms emitted from the target 200 due to the collision may be deposited on the upper surface of the substrate 140 at a high rate.

If no electrical signal is received from the process controller 500 in operation 200, the magnetic field generator control module 600 may determine that the sputtering process is not performed. The movement controller 620 of the magnetic field generator control module 600 prevents the linear motor 330 from operating, thereby stopping movement of the target 200. In operation 210, the current supply controller 610 of the magnetic field generator control module 600 stops current from being supplied to the magnetic field generators 700 or 701.

Thus, a magnetic field is not generated from the magnetic field generators 700 or 701. Consequently, the magnetic field generator control module 600 can prevent the target 200 from being magnetized by the magnetic field generators 700 or 701 while the sputtering process is not performed. In addition, when the dual coil type magnetic field generator 701 is used as shown in FIG. 8, the inner coil 721 and the outer coil 722 may have opposite polarities, such that the effect of an unbalanced magnetron deposition source can be obtained.

According to aspects of the present invention, magnetic field generation toward a target is selectively controlled according to whether a sputtering process is performed, and thus it is possible to prevent the target from being magnetized after the sputtering process. In addition, according to aspects of the present invention, a target is reciprocated below a magnetron, which is a magnetic field generator, during a sputtering process, such that a target material can be uniformly deposited on a substrate.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A magnetic field generation control unit, comprising:
a magnetic field generator to provide a specific magnetic field to a target having a metal material to be deposited on a substrate; and
a magnetic field generator control module electrically connected with the magnetic field generator, to receive an electrical signal, and to selectively supply a current capable of generating the magnetic field to the magnetic field generator.

2. The magnetic field generation control unit according to claim 1, wherein the magnetic field generator includes:
an inner ferrite formed in the shape of a bar having a specific length;
a coil wound around the inner ferrite; and
an outer ferrite surrounding the coil and having an external surface coated with nickel.

3. The magnetic field generation control unit according to claim 1, wherein the magnetic field generator includes:
an inner ferrite formed in the shape of a bar having a specific length;
an inner coil wound around the inner ferrite;
an outer coil wound around the inner coil; and
an outer ferrite surrounding the outer coil and having an external surface coated with nickel.

4. The magnetic field generation control unit according to claim 2, wherein:
the magnetic field generation control unit further comprises only one magnetic field generator; and
the one magnetic field generator is spaced apart from one surface of the target by a specific distance.

5. The magnetic field generation control unit according to claim 2, wherein the magnetic field generation control unit further comprises a plurality of the magnetic field generators parallel to each other and spaced apart from one surface of the target by a specific distance.

6. The magnetic field generation control unit according to claim 1, further comprising:
a process controller electrically connected with the magnetic field generator control module, to control a process of depositing the metal material on the substrate;
wherein the process controller transfers the electrical signal to the magnetic field generator control module when the process of depositing the metal material on the substrate is performed.

7. A magnetron sputtering apparatus having a magnetic field generation control unit, the magnetron sputtering apparatus comprising:
a process chamber having a substrate support on which a substrate is placed;
a target installed above the substrate support in the process chamber, including a metal material to be deposited on the substrate, and arranged so as to be movable along a specific reciprocating movement path;
a magnetic field generator installed above the target in the process chamber, to provide a specific magnetic field to the target;
a process controller to control a process of depositing the metal material on the substrate; and
a magnetic field generator control module electrically connected with the process controller and the magnetic field generator, to receive an electrical signal indicating whether the process is performed from the process controller, to selectively move the target, and to selectively supply a current capable of generating the magnetic field to the magnetic field generator.

8. The magnetron sputtering apparatus according to claim 7, further comprising:
a movement unit connected with the target;
wherein the movement unit includes a fixing frame to fix both sides of the target, a guide frame to guide a sliding movement of the fixing frame, and a linear motor to slide the fixing frame.

9. The magnetron sputtering apparatus according to claim 8, wherein:
the magnetic field generator control module includes a movement controller and a current supply controller;
the movement controller is electrically connected with the linear motor;
the current supply controller is electrically connected with the magnetic field generator; and
when the process of depositing the metal material on the substrate is performed, the magnetic field generator control module receives the electrical signal indicating that the process is performed from the process controller, reciprocates the target using the movement controller and supplies the specific current to the magnetic field generator using the current supply controller.

10. The magnetron sputtering apparatus according to claim 7, wherein the magnetic field generator includes:
an inner ferrite formed in the shape of a bar having a specific length;
a coil wound around the inner ferrite; and
an outer ferrite surrounding the coil and having an external surface coated with nickel.

11. The magnetron sputtering apparatus according to claim 7, wherein the magnetic field generator includes:
an inner ferrite formed in the shape of a bar having a specific length;
an inner coil wound around the inner ferrite;
an outer coil wound around the inner coil; and
an outer ferrite surrounding the outer coil and having an external surface coated with nickel.

12. The magnetron sputtering apparatus according to claim 10, wherein:
the magnetron sputtering apparatus comprises only one of the magnetic field generator; and
the one magnetic field generator is spaced apart from one surface of the target by a specific distance.

13. The magnetron sputtering apparatus according to claim 12, wherein a length direction of the magnetic field generator crosses the reciprocating movement path at right angles.

14. The magnetron sputtering apparatus according to claim 10, wherein the magnetron sputtering apparatus comprises a plurality of the magnetic field generators parallel to each other and spaced apart from one surface of the target by a specific distance.

15. The magnetron sputtering apparatus according to claim 14, wherein a length of the magnetic field generators is in the same direction as the reciprocating movement path.

16. A magnetron sputtering method using a magnetic field generation control unit, the method comprising:
determining, at a process controller, whether a process of depositing a metal material of a target on a substrate is performed; and
determining, at a magnetic field generator control module, whether to supply a current for generating a magnetic field to a magnetic field generator for generating a magnetic field from the target according to whether the process is performed.

17. The magnetron sputtering method according to claim 16, wherein:
the magnetic field generator control module includes a movement controller and a current supply controller; and
when the process of depositing the metal material on the substrate is performed, the magnetic field generator control module receives an electrical signal indicating that the process is performed from the process controller, reciprocates the target using the movement controller, and supplies the specific current to the magnetic field generator using the current supply controller.

18. The magnetic field generation control unit according to claim 3, wherein:
the magnetic field generation control unit comprises only one magnetic field generator; and
the one magnetic field generator is spaced apart from one surface of the target by a specific distance.

19. The magnetic field generation control unit according to claim 3, wherein the magnetic field generation control unit comprises a plurality of the magnetic field generators parallel to each other and spaced apart from one surface of the target by a specific distance.

20. The magnetron sputtering apparatus according to claim 11, wherein:
the magnetron sputtering apparatus comprises only one magnetic field generator; and
the one magnetic field generator is spaced apart from one surface of the target by a specific distance.

21. The magnetron sputtering apparatus according to claim 11, wherein the magnetron sputtering apparatus comprises a plurality of the magnetic field generators parallel to each other and spaced apart from one surface of the target by a specific distance.

22. A magnetron sputtering method to deposit a target material onto a substrate, the method comprising:
transmitting an electrical signal indicating whether a sputtering process is to be performed; and
if the electrical signal indicates that the sputtering process is to be performed,
moving a target along a movement path;
generating a magnetic field; and
surrounding the target with an inert gas so as to deposit the target material onto the substrate.

23. The magnetron sputtering method of claim 22, wherein, if the electrical signal indicates that the sputtering process is not to be performed, the method further comprises:
preventing the target from moving; and
stopping the generation of the magnetic field.

24. The magnetron sputtering method of claim 22, wherein, if the electrical signal indicates that the sputtering process is to be performed, the method further comprises:
supplying current values to at least one of a plurality of magnetic field generators; and
wherein the generating of the magnetic field comprises generating a plurality of magnetic fields based on the current values.

25. The magnetron sputtering method of claim 22, wherein the magnetic field has a strength ranging from 200 gauss to 800 gauss.

26. The magnetron sputtering method of claim 22, wherein:
the transmitting of the electrical signal comprises transmitting an electrical signal indicating that the sputtering process has completed; and
if the electrical signal indicates that the sputtering process has completed, preventing magnetization of the target.

27. A magnetron sputtering apparatus having a magnetic field generation control unit, the magnetron sputtering apparatus comprising:
a process chamber having a substrate support;
a target installed above the substrate support in the process chamber, the target including a metal material to be deposited on a substrate supported by the substrate support, and arranged so as to be movable along a movement path;
a magnetic field generator installed above the target in the process chamber, to provide a magnetic field to the target;
a process controller to control a process of depositing the metal material on the substrate; and
a magnetic field generator control module electrically connected with the process controller and the magnetic field generator, to selectively move the target along the movement path and to selectively supply a current capable of generating the magnetic field to the magnetic field generator, based on whether a sputtering process is to be performed or has been completed.
